(19) United States
(12) Patent Application Publication
(10) Pub. No.: US 2012/0007255 A1
(43) Pub. Date: Jan. 12, 2012

(54) SEMICONDUCTOR DEVICE

(75) Inventors: Hiroshi SHIROTA, Kanagawa (JP); Yasunari Shigemitsu, Itami (JP); Kazunori Hisamura, Itami (JP)

(73) Assignee: RENESAS ELECTRONICS CORPORATION

(21) Appl. No.: 13/166,426

(22) Filed: Jun. 22, 2011

(30) Foreign Application Priority Data
Jul. 8, 2010 (JP) 2010-155408

(51) Int. Cl. H01L 23/528

(52) U.S. Cl. 257/774; 257/E23.153

(57) ABSTRACT

A semiconductor device having a power supply wiring and a ground wiring is provided, which can suppress the occurrence of voltage drop in part of wiring and the occurrence of migration caused by voltage drop. The semiconductor device includes a semiconductor substrate having a main surface, a sheet-like power supply wiring spreading in a stratified form along the main surface of the semiconductor substrate, a sheet-like ground wiring spreading along the main surface of the semiconductor substrate in a stratified form and spacedly a predetermined certain distance from the sheet-like power supply wiring in a direction intersecting the main surface of the semiconductor substrate, a power supply wiring formed over the main surface of the semiconductor substrate and extending in one direction within the main surface of the semiconductor substrate, and a ground wiring formed over the main surface of the semiconductor substrate spacedly a predetermined certain distance from the power supply wiring and extending in the one direction. The sheet-like power supply wiring is electrically coupled with the power supply wiring and the sheet-like ground wiring is electrically coupled with the ground wiring.

### CROSS-REFERENCE TO RELATED APPLICATIONS

The disclosure of Japanese Patent Application No. 2010-155408 filed on Jul. 8, 2010 including the specification, drawings and abstract is incorporated herein by reference in its entirety.

### BACKGROUND

The present invention relates to a semiconductor device and more particularly to a semiconductor device having a power supply wiring and a ground wiring.

With the tendency to higher performance of semiconductor devices, reduction of size and higher integration are being promoted. For the reduction of size and higher integration, a semiconductor integrated circuit having a multi-layer interconnection structure is now most popular for the purpose of diminishing the area occupied by power supply wiring.

In a semiconductor integrated circuit having a multi-layer interconnection structure, a power supply wiring region (a high potential loading wiring region) and a ground wiring region (a grounding wiring region), which configure standard cells on a main surface of a semiconductor substrate, are coupled electrically to a power supply wiring and a ground wiring both overlying the semiconductor substrate. This configuration is disclosed, for example, in Japanese Unexamined Patent Publication Nos. 2010-34407 (Patent Document 1), 2008-182058 (Patent Document 2) and 2004-296695 (Patent Document 3).

In each of the semiconductor devices disclosed in the above patent documents, for example the power supply wiring and ground wiring present in upper layers have each an elongated shape. The power supply wiring region and the ground wiring region, which configure standard cells in a lower layer (on a main surface of a semiconductor substrate), also have each an elongated shape. Upper wiring and lower wiring are coupled together electrically through a via (a contact portion) which provides an electrical coupling between layers.

### SUMMARY

In the related-art semiconductor device having a multi-layer interconnection structure disclosed in each of the above patent documents, for example power supply wiring and ground wiring present in upper layers have each an elongated shape when seen in plan and the wirings are used properly in accordance with extending directions of those elongated wirings. For example, wiring extending in a first direction (lateral direction) in plan is formed in a top layer of the semiconductor device and serves as a power supply wiring. Just under the top layer is formed a wiring extending in a second direction (longitudinal direction) in plan and serves as a ground wiring. Thus, it has been a custom to design such elongated wirings of different properties so as to dispose them separately according to their extending directions when seen in plan.

However, as the semiconductor devices become smaller in size and higher in integration, and with consequent microminiaturization in size of wirings and pads which are for the supply of electric signals to the wirings, a sectional area of a coupling portion between pad and wiring may become smaller. In this case, an electric resistance between the pads and the wirings becomes higher, with consequent likelihood of an increase in voltage drop. That is, there arises the possibility of a lowering in the supply of electric power in the semiconductor device concerned.

Moreover, in the aforesaid region which has become smaller in sectional area, there may occur a local increase in current value. As a result, there arises the possibility that a wiring failure called migration may occur.

In the recent semiconductor devices, a core power supply is becoming more and more low in voltage. Accordingly, it is becoming extremely important to diminish voltage drop and stabilize the supply voltage. For example, heretofore the voltage value of the core power supply has mainly been 3.3V, but recently it has decreased to as low as 1.2V or so. On the other hand, the operating current in the recent semiconductor devices is in many cases 1A or more as is the case with the related semiconductor devices. Thus, it is difficult to diminish the voltage drop and difficult to stabilize the semiconductor device voltage and supply voltage.

The present invention has been accomplished in view of the above-mentioned problems and it is an object of the invention to provide a semiconductor device having a power supply wiring and a ground wiring and capable of suppressing the occurrence of voltage drop and migration in part of the wirings.

The semiconductor device of the present invention includes a semiconductor substrate having a main surface, a sheet-like power supply wiring spreading in a stratified state along the main surface of the semiconductor substrate, a sheet-like ground wiring spreading in a stratified form along the main surface of the semiconductor substrate and spacedly a predetermined certain distance from the sheet-like power supply wiring in a direction intersecting the main surface of the semiconductor substrate, a power supply wiring formed over the main surface of the semiconductor substrate and extending in one direction within the main surface, and a ground wiring formed over the main surface of the semiconductor substrate spacedly a predetermined certain distance from the power supply wiring and extending in a direction along the one direction. The sheet-like power supply wiring is coupled electrically to the power supply wiring, while the sheet-like ground wiring is coupled electrically with the ground wiring.

### EFFECT OF THE INVENTION

According to the semiconductor device of the present invention, since it is provided with a sheet-like power supply wiring and a sheet-like ground wiring both spreading in a stratified form, a sectional area of each of coupling portions for coupling between those wirings and pads can be made sufficiently large. Consequently, an electric resistance value at the coupling portion is diminished and the occurrence of voltage drop and migration is suppressed as a whole. According to the present invention, moreover, a sectional area of the sheet-like power supply wiring can be made larger than that of the related elongated power supply wiring and therefore also from this point the occurrence of voltage drop and migration is suppressed as a result.

### BRIEF DESCRIPTION OF THE DRAWINGS

FIG. 1 is a schematic diagram of a semiconductor device according to a first embodiment of the present invention;

FIG. 2 is a schematic sectional view showing the configuration of each of wiring layers stacked vertically of a semiconductor chip shown in FIG. 1;

FIG. 3 is a schematic diagram showing the configuration of a sheet-like power supply wiring and a sheet-like ground wiring in the semiconductor device of the first embodiment;

FIG. 4 is a schematic diagram showing in plan the sheet-like power supply wiring shown in FIG. 3;

FIG. 5 is a schematic diagram showing in plan the sheet-like ground wiring shown in FIG. 3;

FIG. 6 is a schematic plan view showing a part of a wiring mode in a top wiring layer of the stacked structure in the first embodiment;

FIG. 7 is a schematic plan view showing a part of a wiring mode in a wiring layer disposed just under the wiring layer shown in FIG. 6;

FIG. 8 is a schematic plan view showing in more detail the wiring mode of the wiring layer shown in FIG. 6;

FIG. 9 is a schematic plan view showing in more detail the wiring mode of the wiring layer shown in FIG. 7;

FIG. 10 is a schematic plan view showing a wiring mode of a bottom wiring layer in FIG. 2;

FIG. 11 is a schematic plan view showing a part of a wiring mode of a top wiring layer in a stacked structure of a semiconductor device as a reference example which is for comparison with the first embodiment;

FIG. 12 is a schematic diagram showing the configuration of a sheet-like power supply wiring and that of a sheet-like ground wiring in a semiconductor device according to a second embodiment of the present invention;

FIG. 13 is a schematic sectional view showing the configuration of each of wiring layers stacked vertically of a semiconductor chip like FIG. 2 in a semiconductor device according to a third embodiment of the present invention;

FIG. 14 is a schematic diagram showing the configuration of a sheet-like power supply wiring and that of a sheet-like ground wiring in a semiconductor device according to a fourth embodiment of the present invention;

FIG. 15 is a schematic plan view showing the layout of through vias coupled with a sheet-like power supply wiring in one example of a fifth embodiment of the present invention;

FIG. 16 is a schematic plan view showing the layout of a sheet-like ground wiring and that of through vias in one example of the fifth embodiment;

FIG. 17 is a schematic plan view showing the layout of through vias coupled with a sheet-like power supply wiring in another example of the fifth embodiment different from the example of FIG. 15; and

FIG. 18 is a schematic plan view showing the layout of a sheet-like ground wiring and that of through vias in another example of the fifth embodiment different from the example of FIG. 16.

### DETAILED DESCRIPTION

Embodiments of the present invention will be described below with reference to the accompanying drawings. In the drawings the same or equivalent portions are identified by the same reference numerals, and repeated explanations thereof will be omitted.

### First Embodiment

First, a description will be given below about the whole of a semiconductor device according to a first embodiment of the present invention.

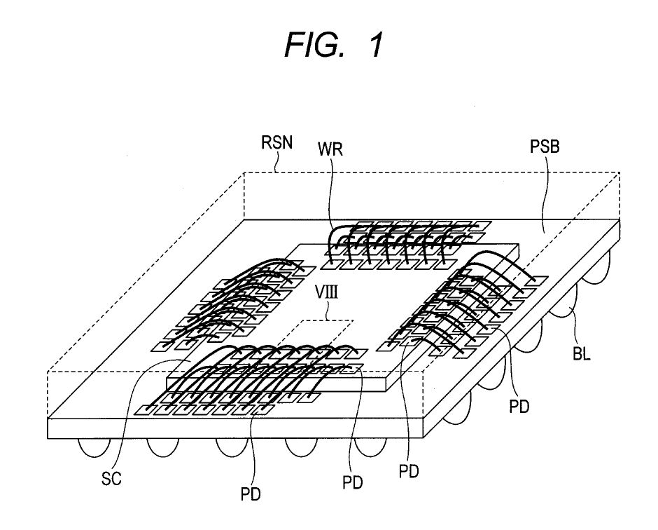

Referring to FIG. 1, the semiconductor device (SoC: System-on-a-Chip) of this first embodiment is a BGA (Ball Grid Array package) having a package substrate PSB, a semiconductor chip SC, molding resin RSN, and balls BL.

The package substrate PSB is preferably a structure of, for example, a flat plate shape formed of a ceramic material superior in thermal conductivity such as, for example, silicon nitride or aluminum nitride. The semiconductor chip SC is formed by a semiconductor substrate using, for example, a single crystal of silicon (silicon wafer) as a substrate. On one main surface (an upper main surface in FIG. 1) of the semiconductor chip SC are formed a large number of components which configure a semiconductor integrated circuit, e.g., multi-layer interconnection structure and circuit elements.

Pads PD are formed on an upper-side main surface of the package substrate PSB and that of the semiconductor chip SC.

The pads PD are exposed regions of a thin metal film for applying a desired voltage to wiring lines, etc. in an integrated circuit formed on the semiconductor chip SC. Therefore, the pads PD are electrically coupled with wiring lines, etc. in the integrated circuit formed on the semiconductor chip SC.

Plural pads PD are arranged for example in two rows on the main surface of the semiconductor chip SC and that of the package substrate PSB. However, the number of juxtaposed rows of the pads PD and that of the pads arranged in each row are arbitrary.

The molding resin RSN indicated by dotted lines in FIG. 1 is a resin material, e.g., epoxy resin. The molding resin RSN is disposed so as to cover, from above, one main surface (the upper-side main surface in FIG. 1) of the package substrate PSB and the integrated circuit formed on one main surface (the upper-side main surface in FIG. 1) of the semiconductor chip SC.

Thus, the upper-side main surface of the semiconductor chip SC and that of the package substrate PSB are sealed with the molding resin RSN. Consequently, fine circuits formed on the semiconductor chip SC can be prevented from undergoing such an inconvenience as their normal operations being obstructed under the influence of foreign matters such as particles and water. It is also possible to prevent normal operations of the fine circuits from being obstructed under the influence of light. Further, since the semiconductor chip SC is covered with the molding resin RSN, it is possible to ensure insulation between the circuits formed on the semiconductor chip SC and the exterior.

The semiconductor device of FIG. 1 is placed onto another substrate (not shown) formed with external circuits and it is thereby used in a state integrated with the another substrate. At the balls BL, which are solder balls, the semiconductor device operates while inputting and outputting electric signals from and to the external circuits.

The pads PD formed on the main surface of the package substrate PSB are electrically coupled with the balls BL through conductive portions which extend through the package substrate PSB from one main surface of the package substrate and reach the other main surface (a lower-side main surface in FIG. 1) of the package substrate. The pads PD on the package substrate PSB and the pads PD on the semiconductor chip SC are coupled together electrically through metallic wires WR.

With the above configuration, electric signals inputted to the interior of the semiconductor device from the balls BL pass through the conductive portions formed in the interior of the package substrate PSB and reach the pads PD formed on the package substrate PSB. Further, with the wires WR, the electric signals reach the pads PD on the semiconductor chip SC and are inputted to the integrated circuit of the semiconductor chip SC. Through this route there are made input and output of electric signals between the substrate of the semiconductor device and the integrated circuit of the semiconductor chip SC.

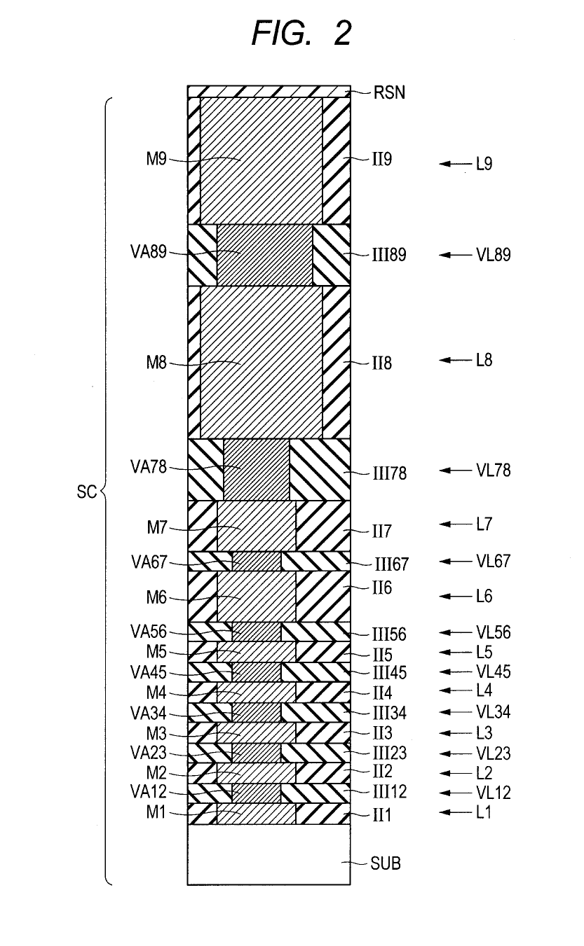

Referring to FIG. 2, a large number of wiring layers are stacked between lower- and upper-side main surfaces of the semiconductor chip SC. These wiring layers configure a multi-layer interconnection structure, serving as apart of the integrated circuit. More specifically, on one main surface (an upper-side main surface in FIG. 2) of a semiconductor substrate SUB, which is formed for example by a single crystal of silicon, there are formed wiring layer L1, through layer VL12, wiring layer L2, through layer VL23, wiring layer L3, through layer VL34, wiring layer L4, through layer VL45, wiring layer L5, through layer VL56, wiring layer L6, through layer VL67, wiring layer L7, through layer VL78, wiring layer L8, through layer VL89, and wiring layer L9, in this order. All of these wiring layers are formed so as to extend along the main surfaces of the semiconductor chip SC. Molding resin RSN is disposed so as to cover, from above, the wiring layer L9 as the top layer in the stacked structure.

A metal wiring M1 as a constituent of the integrated circuit is formed in the wiring layer L1 and a through via VA12 is formed in the through layer VL12. Likewise, metal wirings M2, M3, M4, M5, M6, M7, M8, and M9, are formed in the other wiring layers L2, L3, L4, L5, L6, L7, L8, and L9, respectively. Further, through vias VA23, VA34, VA45, VA56, VA67, VA78, and VA89, are formed in the other through layers VL23, VL34, VL45, VL56, VL67, VL78, and VL89, respectively.

For example, the metal wirings M9 and M8 are coupled together electrically by the through via VA89 interposed between them. This is because the through via VA89 is formed by a conductor, e.g., metal, which fills the interior of a through hole formed in an insulating layer configuring the through layer VL89. This is also true of the other through vias which provide couplings between the other metal wirings.

The metal wirings M1 to M9 are each formed by a thin metal film of, say, aluminum, copper, or an alloy thereof.

Although in FIG. 2 there are a total of nine metal wirings M1 to M9, the number of metal wirings to be stacked is arbitrary.

The wiring layers L1 to L7 are circuit regions which configure a principal portion of the integrated circuit on the semiconductor chip SC. On the other hand, the wiring layer L8 and the wiring layer L9 as the top layer are circuit regions which configure both power supply wiring and ground wiring in the semiconductor chip SC. The wiring layers L8 and L9 are vertically thicker than the other wiring layers.

An insulating film II1 is formed in the wiring layer L1 at the region where the metal wiring M1 is not formed in plan. An insulating layer II12 is formed in the through layer VL12 at the region where the metal wiring M1 is not formed in plan. Likewise, insulating films II2, II3, II4, II5, II6, II7, II8, and II9, are formed in the other wiring layers L2, L3, L4, L5, L6, L7, L8, and L9, respectively. Insulating films II23, II34, II45, II56, II67, II78, and II89, are formed in the other through layers VL23, VL34, VL45, VL56, VL67, VL78, and VL89, respectively. It is preferable that these insulating films be formed, for example, by silicon oxide film or silicon nitride film.

FIG. 2 is a sectional view showing only the configuration of each of various wiring layers present in the interior of the semiconductor chip SC. That is, as to the metal wirings M1, etc. formed in the wiring layers, plural types are present and cannot be defined unambiguously. In other words, such a rectilinearly and uniformly stacked configuration of wiring layers from the top to the bottom layer as shown in FIG. 2 is not always present actually. In FIG. 2, a metal wiring, e.g., the metal wiring M1, is illustrated as a generic term for metal wirings formed in the wiring layer L1. As to the wiring layers L1 to L7, they are shown schematically like extending all in the same direction (the direction perpendicular to the paper surface) in FIG. 2, but actually adjacent wiring layers are formed so that the wiring lines formed in the respective wiring layers are different in their extending directions (for example, intersect each other perpendicularly). Regarding each of the wiring layers L8 and L9, a planarly spread wiring like sheet is formed as will be described later.

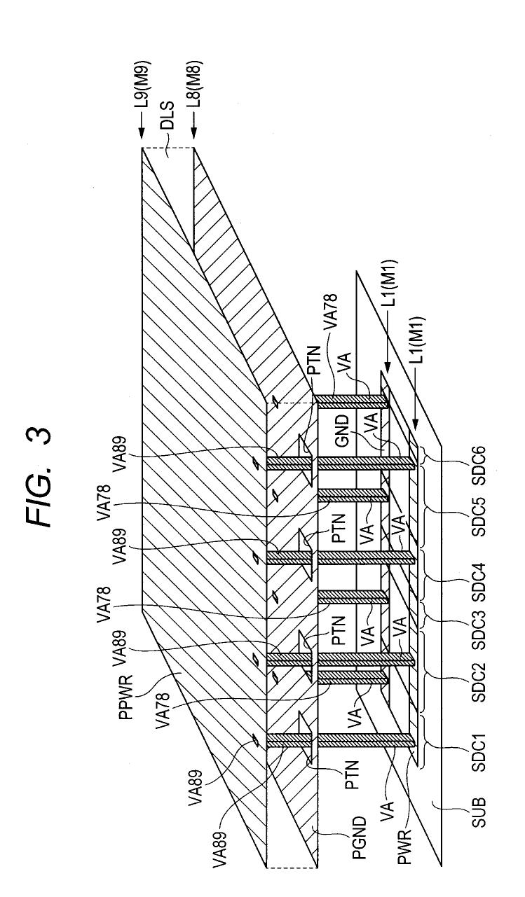

Referring to FIG. 3, a sheet-like power supply wiring PPWR is formed in the wiring layer L9. The sheet-like power supply wiring PPWR is a metal wiring which is apart of the metal wiring M9 in the wiring layer L9 and which spreads in a stratified form along a main surface of the wiring layer L9. In other words, the sheet-like power supply wiring PPWR is formed integrally so as to spread over a wide range to occupy the greater part (a principal area) in a direction along a main surface of the semiconductor substrate SUB. For example, the sheet-like power supply wiring PPWR is formed so as to occupy the greater part (e.g., 50% or more) of the area in a direction along the main surface of the semiconductor substrate SUB in the wiring layer L9.

A sheet-like ground wiring GND is formed in the wiring layer L8. The sheet-like ground wiring PGND is a metal wiring which is a part of the metal wiring M8 in the wiring layer L8 and which spreads in a stratified form along a main surface of the wiring layer L8. That is, the sheet-like ground wiring PGND spreads in a stratified form spacedly a predetermined certain distance from the sheet-like power supply wiring PPWT in a direction (vertical direction in FIG. 3) intersecting the main surface of the semiconductor substrate SUB. In other words, when seen in plan, the sheet-like ground wiring PGND is formed integrally so as to spread over a wide range so as to occupy a principal area of the wiring layer L8 in a direction along the main surface of the semiconductor substrate SUB. For example, the sheet-like ground wiring PGND is formed so as to occupy the greater part (e.g., 50% or more) of the area in a direction along the main surface of the semiconductor substrate SUB in the wiring layer L8.

A through hole VL89 (not shown) is disposed between the wiring layers L9 and L8. It is preferable that the sheet-like power supply wiring PPWR and the sheet-like ground wiring PGND overlap each other at least partially in plan. Preferably, at the greater part of the region of the sheet-like power supply wiring PPWR and that of the sheet-like ground wiring PGND both overlap each other in plan.

That both overlap each other at the greater part of the region of the sheet-like power supply wiring PPWR and that of the sheet-lie ground wiring PGND indicates that both overlap each other at respective portions of 50% or more in terms of area when seen in plan.

In the through layer VL89, a dielectric layer DLS is disposed in the overlapped region in plan between the sheet-like power supply wiring PPWR and the sheet-like ground wiring PGND. Preferably, the dielectric layer DLS contains at least one member selected from the group consisting of silicon nitride, aluminum oxide, tantalum oxide, lanthanum oxide, hafnium oxide, zirconium oxide, silicate, aluminate, hafnium silicate, hafnium aluminum oxy-nitride, and yttrium oxide. The dielectric layer DLS may be disposed in the region where the sheet-like power supply wiring PPWR and the sheet-like ground wiring PGND do not overlap each other in plan.

If the dielectric layer is disposed at an overlapping position with the sheet-like power supply wiring PPWR and the sheet-like ground wiring PGND in plan, the portion configured by the wirings PPWR, PGND and the dielectric layer DLS configures a capacitor in the entire semiconductor device.

Referring to FIGS. 3 to 5, through vias VA extend from the sheet-like power supply wiring PPWR toward the sheet-like ground wiring PGND. The through vias VA89 are electrically coupled with the sheet-like power supply wiring PPWR at coupling portions with PPWR shown in FIG. 3. The through vias VA89 further extend downwards through through-holes called patterns PTN formed in part of the sheet-like ground wiring PGND. Below the through vias VA89 there extend the foregoing through vias VA78 and VA67, which are generically termed through vias VA in FIG. 3. The through vias VA reach a power supply wiring PWR in the wiring layer L1. The power supply wiring PWR in the wiring layer L1 is a part of the metal wiring M1. In this way the sheet-like power supply wiring PPWR in the wiring layer L9 and the power supply wiring PWR in the wiring layer L1 are coupled together electrically.

Through vias VA78 extend from the sheet-like ground wiring PGND toward the wiring layer L1. The through vias VA extending below the through vias 78 reach a ground wiring GND in the wiring layer L1. The ground wiring GND in the wiring layer L1 is a part of the metal wiring M1. In this way the sheet-like ground wiring PGND in the wiring layer L8 and the ground wiring GND in the wiring layer L1 are coupled together electrically.

In the wiring layer L1 and on the main surface of the semiconductor substrate SUB there are arranged a plurality of standard cells SDC1, SDC2, SDC3, SDC4, SDC5 and SDC6 in a sandwiched state in between the power supply wiring PWR and the ground wiring GND.

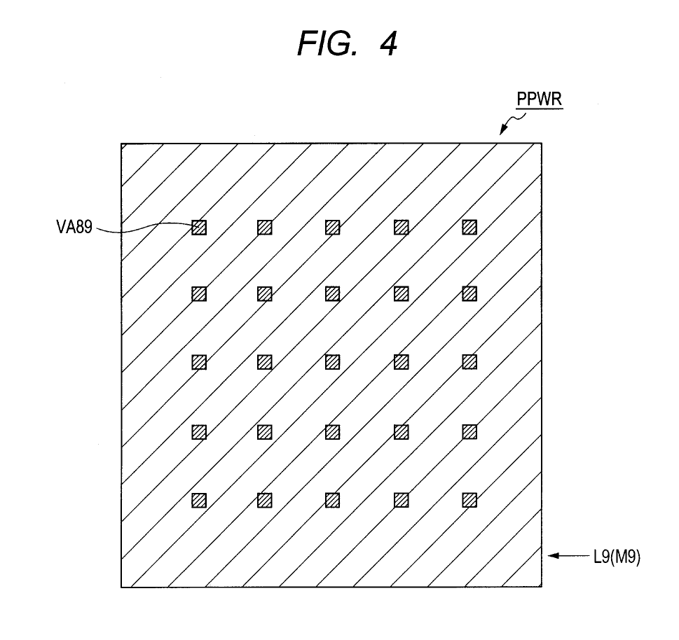

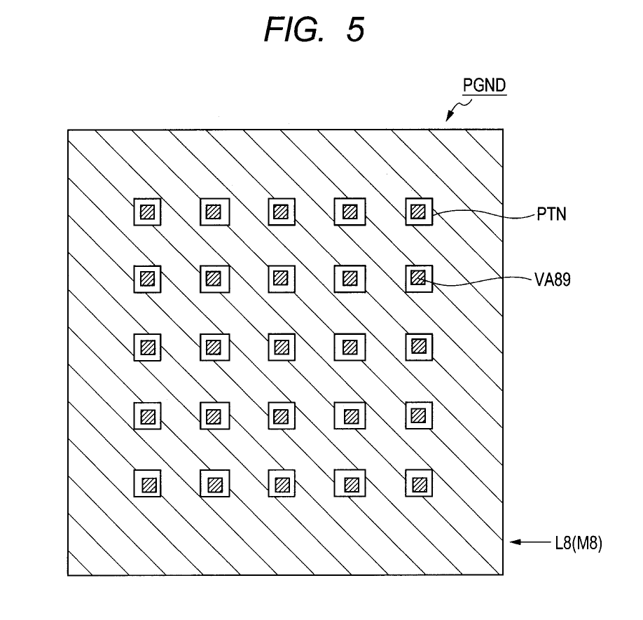

In FIGS. 4 and 5, the sheet-like power supply wiring PPWR, the sheet-like ground wiring PGND and the through vias VA89 are each in a square shape when seen in plan, provided their shape is not limited to the square shape, but may take an arbitrary planar shape, e.g., a rectangular, circular or elliptic shape. Also as to the number and shape of the through vias VA89 and patterns PTN, no limitation is made to the examples shown in FIGS. 4 and 5.

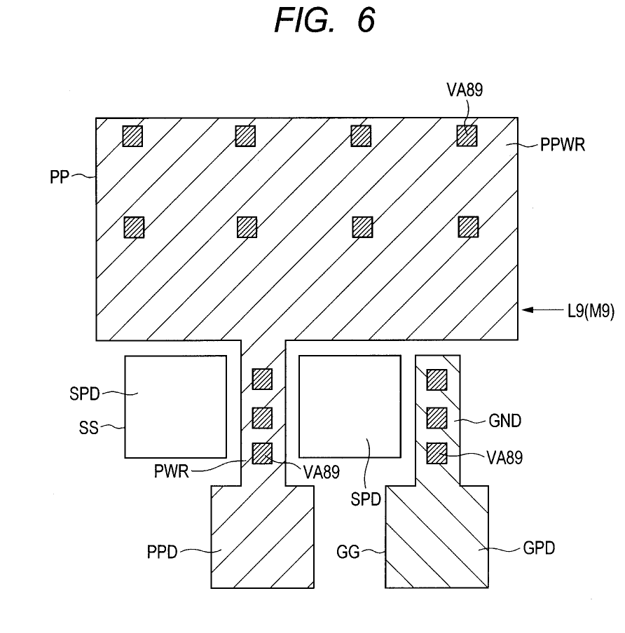

Referring to FIG. 6, in the wiring layer L9 there are formed a power supply wiring PWR (a first wiring portion), a ground wiring GND (a second wiring portion), a power supply pad PPD (a first pad electrode) and a ground pad GPD (a second pad electrode). All of these are constituent portions of the metal wiring M9. The region shown in FIG. 6 corresponds to a region VIII indicated with a dotted line in FIG. 1.

The power wiring PWR formed in the wiring layer L9, when seen in plan, is electrically coupled with the sheet-like power supply wiring PPWR and the power supply pad PPD. Thus, the power supply pad PPD functions as a pad for the supply of supply voltage to the region comprised of the sheet-like power supply wiring PPWR and the power supply wiring PWR.

The ground wiring GND formed in the wiring layer L9 is electrically coupled with the ground pad GPD when seen in plan. Further, as will be described later, the ground wiring GND in the wiring layer L9 is electrically coupled with the sheet-like ground wiring PGND through a second ground wiring GND in the wiring layer L8. Thus, the ground pad GPD functions as a pad for the supply of ground voltage to both second ground wiring GND and sheet-like ground wiring PGND in the wiring layer L8.

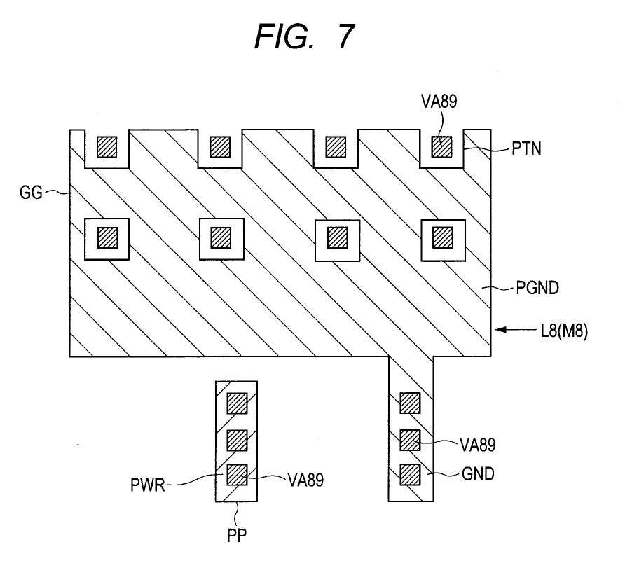

Through vias VA89 extend from the power supply wiring PWR in FIG. 6 toward the wiring layer L8 like the sheet-like power supply wiring PPWR. In the wiring layer L8 is formed a second power supply wiring PWR as shown in FIG. 7 and the power supply wiring PWR in the wiring layer L9 shown in FIG. 6 is coupled with the second power supply wiring PWR in the wiring layer L8 shown in FIG. 7 through the through vias VA89. Also below the second power supply wiring PWR there may extend through vias VA89, which may reach the power supply wiring PWR in the wiring layer L1. In this case, the power supply wiring PWR in FIG. 6 is electrically coupled with the power supply wiring PWR in the wiring layer L1 like the sheet-like power supply wiring PPWR. The sheet-like power supply wiring PPWR, the power supply wiring PWR and the power supply pad PPD are all regions electrically coupled with the power supply wiring PWR in the wiring layer L1, so are here defined as a power supply wiring region PP altogether.

Also from the ground wiring GND in FIG. 6 there extend through vias VA89 toward the wiring layer L8. The through vias VA89 in question are coupled to the second ground wiring GND formed in the wiring layer L8 as shown in FIG. 7. The second ground wiring GND is coupled with the sheet-like ground wiring PGND formed in the wiring layer L8. As noted above, the sheet-like ground wiring PGND is electrically coupled with the ground wiring GND in the wiring layer L1 through the through vias VA78. In connection with the second ground wiring GND, through vias VA89 may extend also below the wiring layer L8 and may reach the ground wiring GND in the wiring layer L1. In this case, the ground wiring GND in FIG. 6 is electrically coupled with the ground wiring GND in the wiring layer L1. Thus, the ground wiring GND, the second ground wiring GND in the wiring layer L8, the sheet-like ground wiring PGND and the ground pad GPD are all regions electrically coupled with the ground wiring GND in the wiring layer L1, so are here defined as a ground wiring region GG altogether.

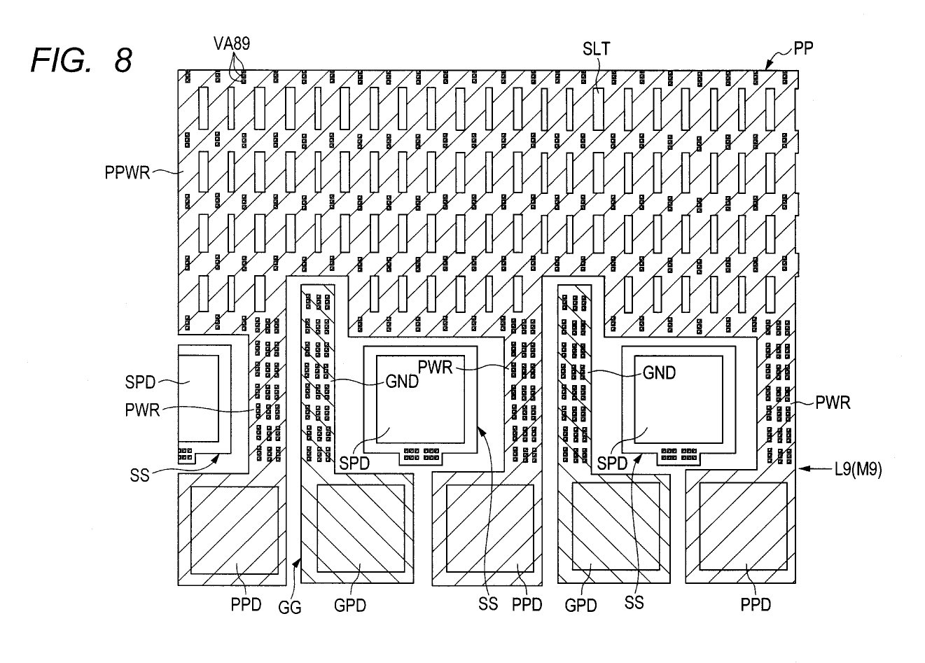

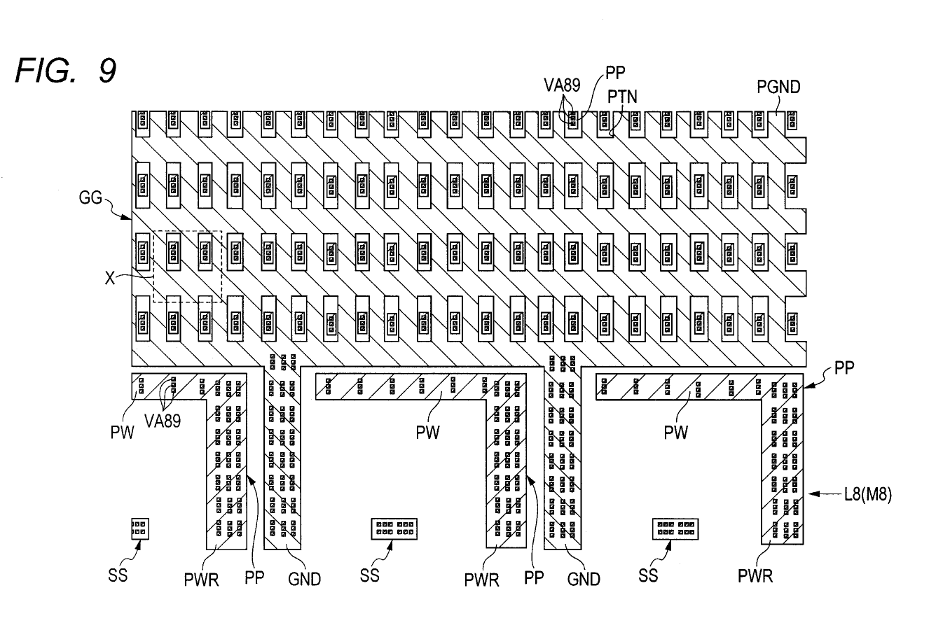

FIG. 8 illustrates in more detail the wiring layer L9 shown in FIG. 6 and FIG. 9 illustrates in more detail the wiring layer L8 shown in FIG. 7. Referring to FIGS. 8 and 9, the sheet-like power supply wiring PPWR in the wiring layer L9 has a generally quadrangular (rectangular) plane shape. Through vias VA89 (third through holes) are coupled at predetermined certain intervals to the sheet-like power supply wiring PPWR. Through vias VA89 coupled to a part (coupling portions) of a lower surface of the sheet-like power supply wiring PPWR in the wiring layer L9 reach the underlying wiring layer L8. The through vias VA89 in question further extend downwards beyond the wiring layer L8, reaching the power supply wiring PWR in the wiring layer L1.

At this time, the through vias VA89 extend so as to reach positions overlapping the sheet-like ground wiring PGND in plan. Therefore, in the sheet-like ground wiring PGND, the environs in plan of the reaching portions of the through vias VA89 become patterns PTN, which are apertures with the sheet-like ground wiring PGND not disposed therein. In the interior of each pattern PTN which is an aperture there is formed an island-like power supply wiring region PP by the same layer as the sheet-like ground wiring PGND. The through vias VA89 are formed so as to reach the power supply wiring regions PP respectively. In lower surfaces of the power supply wiring regions PP are formed through vias respectively which further extend toward the wiring layer L1.

The through vias VA89 shown in FIGS. 8 and 9 are formed in such a manner that three fine through vias gather close to one another to form one set. In the illustrated example, one set of through vias correspond to one through via VA89 shown in FIGS. 6 and 7.

As to the sheet-like power supply wiring PPWR shown in FIG. 8, it is preferable that a plurality of rectangular slits SLT (apertures) be formed in a partial region when seen in plan. In FIG. 8, slits SLT are arranged regularly (in a matrix shape) on the sheet-like power supply wiring PPWR, but the spacing between adjacent slits SLT may be different region by region of the sheet-like power supply wiring PPWR.

In FIG. 8 there are formed a power supply wiring region PP, the power supply wiring region PP being comprised of a sheet-like power supply wiring PPWR, power supply wirings (first wiring portions) PWR and power supply pads PPD, which are electrically coupled together, ground wiring regions GG each comprised of a ground pad GPD and a ground wiring (a second wiring portion) GND, and signal wiring regions SS each comprised of a signal pad SPD and a region where through vias VA89 are formed. Thus, the pads PD shown in FIG. 1 include the power supply pads PPD, ground pads GPD and signal pads SPD, which are shown in FIG. 8.

In the wiring layer L8 shown in FIG. 9, each power supply wiring region PP is comprised of a power supply wiring PWR and a power supply wiring PW both coupled together electrically. The power supply wiring PWR indicates a partial region of the power supply wiring region PP positioned in an overlapping region with the power supply wiring PWR in the wiring layer L9 when seen in plan. In the through layer VL89 between the wiring layers L9 and L8 there are formed through vias VA89. The through vias VA89 are each formed by a conductor filled in the interior of a first through hole formed in an interlayer dielectric film which configures the through layer VL89. The first through hole is for exposing a part of a lower surface of the power supply wiring PWR in the wiring layer L9 and a part of an upper surface of the power supply wiring PWR in the wiring layer L8.

The power supply wiring PW indicates a partial region of the power supply wiring region PP in the other region (the region overlapping the sheet-like power supply wiring PPWR in the wiring layer L9 when seen in plan) than the region overlapping the power supply wiring PWR in the wiring layer L9 when seen in plan.

In the wiring layer L8, the ground wiring region GG is comprised of a sheet-like ground wiring PGND and ground wirings (third wiring portions) GND, which are coupled together electrically. The through vias VA89 disposed on the surfaces of the ground wirings GND in the wiring layer L8 are for coupling the ground wirings GND in the wiring layer L9 and the ground wirings GND in the wiring layer L8 with each other electrically. The through vias VA89 for coupling the ground wirings GND in the wiring layers L8 and L9 are each formed by a conductor which fills the interior of a through hole (a second through hole) formed in the interlayer dielectric film. This through hole is for exposing a part of a lower surface of each ground wiring GND in the wiring layer L9 and a part of an upper surface of each ground wiring GND in the wiring layer L8. The ground wirings GND in the wiring layers L9 and L8 are disposed in a mutually overlapping position when seen in plan.

It is preferable that the through vias VA89 formed in the interiors of the first and second through holes described above be formed so as to pass through an insulating film II89 (an interlayer dielectric film) which configures the through layer VL89.

In the wiring layer L9, as shown in FIG. 8, it is preferable that the number of through vias VA89 (or second through holes) in each ground wiring GND coupled to the ground pad GPD be larger than the number of through vias VA89 (or first through holes) formed in the power supply wiring PWR disposed between the sheet-like power supply wiring PPWR and the power supply pad PPD. In this case, the ground wirings GND in the wiring layers L9 and L8 can be electrically coupled together positively through the through vias VA89.

The coupling portions for coupling with the through vias VA89 in each signal wiring region SS in the wiring layer L9 are arranged such that they extend so as to reach the position where they overlap the coupling portions of the through vias VA89 in the associated signal wiring region SS in the wiring layer L8 when seen in plan.

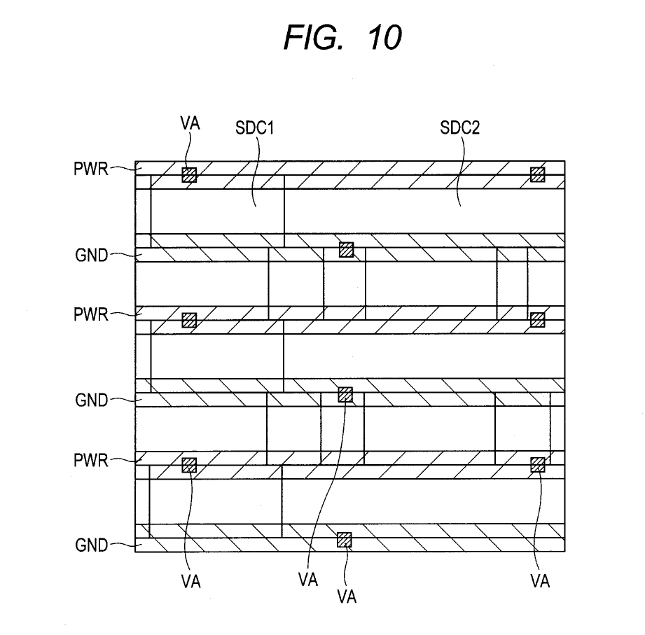

Referring to FIG. 10, the above through vias VA extend downwards through the stacked structure and reach the power supply wiring PWR and the ground wiring GND both configuring the wiring layer L1 as the bottom layer. In the wiring layer L1 are formed standard cells SDC1 and SDC2.

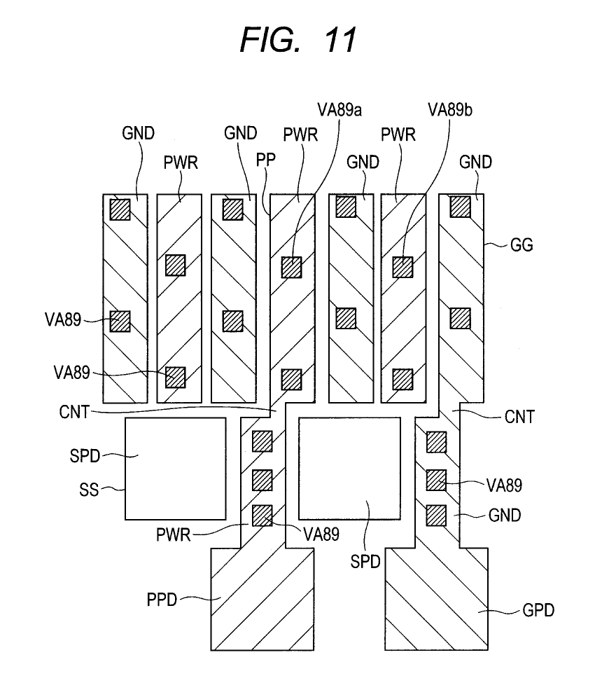

The following description is now provided about the function and effect of the semiconductor device of this embodiment while making comparison with FIG. 11.

FIG. 11 is a plan view showing the configuration of a wiring layer L9 in a semiconductor device as a reference example. In FIG. 11, in comparison with FIG. 6 related to this embodiment, the portion of a power supply wiring region PP which portion corresponds to the sheet-like power supply wiring PPWR in FIG. 6 is comprised of plural power supply wirings PWR each having an elongated shape in plan. That is, in FIG. 11, a plurality of linear regions having the same shape as the power supply wiring PWR in FIG. 6 exhibit the same function as the sheet-like power supply wiring PPWR in FIG. 6. In FIG. 11, in the region where the sheet-like power supply wiring PPWR in FIG. 6 is formed, there are formed a plurality of power supply wirings PWR and ground wirings GND each having an elongated shape and arranged alternately side by side at predetermined certain intervals.

In the power supply wiring region PP in FIG. 11, a power supply wiring PWR (disposed at the position of the sheet-like power supply wiring PPWR in FIG. 6) and a power supply wiring PWR (as the first wiring portion in FIG. 6) coupled directly to a power supply pad PPD are electrically coupled together at a coupling portion CNT. In the case of FIG. 11, the width (in the right and left direction in FIG. 11) of the coupling portion may become very narrow, depending on positions where the power supply wirings PWR are formed. Consequently, in the power supply wiring region PP in FIG. 11, a sectional area of the current path becomes smaller in the coupling portion which has become narrow, with consequent increase of electric resistance at the coupling portion CNT. Once the electric resistance at the coupling portion CNT becomes large, voltage drop becomes large in the vicinity of the coupling portion CNT and the power supply capability of the entire semiconductor device is deteriorated. Moreover, current concentration occurs in the coupling portion CNT which has become narrow, so that there arises the possibility of occurrence of a wiring failure (migration) at the coupling portion CNT.

In this embodiment shown in FIG. 6, however, the sheet-like power supply wiring PPWR spreads in a stratified form so as to occupy a large area at the main surface of the wiring layer L9. Therefore, for example, irrespective of the position of the power supply wiring PWR as the first wiring portion, the width of the coupling portion between the sheet-like power supply wiring PPWR and the power supply wiring PWR becomes almost equal to the width of the power supply wiring PWR.

Thus, since the proportion of the area occupied by the sheet-like power supply wiring PPWR relative to the main surface of the wiring layer L9 becomes large, it is possible to suppress the occurrence of voltage drop and migration in the region coupled to the power pad PPD (power supply wiring PWR).

It is necessary to take the following measure in order to electrically couple for example two power supply wirings PWR (e.g., one power supply wiring PWR coupled to the power supply pad PPD and with through vias VA89a coupled thereto and another power supply wiring PWR formed spacedly from the one power supply wiring PWR and with through vias VA89b coupled thereto) in FIG. 11, (couple the power supply pad PPD with those two power supply wirings PWR electrically). In the wiring layer L9, the first power supply wiring PWR with through vias VA89a coupled thereto and the second power supply wiring PWR with through vias VA89b coupled thereto are discontinuous with each other.

Therefore, in the wiring layer L8 there is formed a power supply wiring PWR coupled to both through vias VA89a and VA89b. That is, in order to couple the first and second power supply wirings PWR electrically with each other, it is necessary to utilize the two wiring layers L9 and L8.

In this embodiment, however, the through vias coupled to the sheet-like power supply wiring PPWR which spreads over a wide range in a stratified form are coupled together electrically by the sheet-like power supply wiring PPWR. Therefore, for coupling the power supply pad PPD and through vias electrically with each other, it is not necessary to form a structure that straddles the two wiring layers L9 and L8. That is, since such extra through vias as shown in FIG. 11 are not included in the current path from the power supply pad PPD up to the power supply wiring PWR formed in the wiring layer L1, a voltage drop caused by the presence of the through vias is suppressed. Also from this point it is possible to suppress a lowering in the power supply capability of the semiconductor device concerned.

For example as shown in FIG. 2, the wiring layer L9 as the top layer and the wiring layer L8 located just under L9 are larger in vertical thickness than the other wiring layers. Therefore, wiring patterns of a narrow width in the direction along the main surface, for example like the power supply wirings PWR and ground wirings GND shown in FIG. 11, become larger in an aspect ratio of thickness and width. Consequently, the power supply wirings PWR and ground wirings GND in FIG. 11 become unstable structurally and there is the possibility that the wirings in question may fall down.

However, the sheet-like power supply wiring PPWR and the sheet-like ground wiring PGND both used in this embodiment are wide in the direction along the main surface. Therefore, even if these wiring patterns become larger in thickness, the aspect ratio of thickness and width becomes smaller. Accordingly, the wirings formed are stable structurally and are less likely to fall down.

In this embodiment, moreover, the sheet-like power supply wiring PPWR and the sheet-like ground wiring PGND each have a simple shape spreading in a stratified form. Therefore, the design rule is eased in comparison with the case where such narrow linear power supply wirings PWR and ground wirings GND as shown in FIG. 11 are formed in a large number. Consequently, it is possible to reduce the cost for fabricating a mask to be used in photolithography.

Further, in the semiconductor device of this embodiment, the sheet-like power supply wiring PPWR and the sheet-like ground wiring PGND, as well as the dielectric layer DLS disposed between them, configure a decoupling capacitor (a parallel plate capacitor). By the decoupling capacitor is meant a structure which function to store an electric charge in advance and supplies it to a place where variations in the quantity of electric charge occurs, in order to compensate for the said variations. With this structure, it is possible to more stabilize the operation of the semiconductor device.

In this embodiment, as noted above, the sheet-like power supply wiring PPWR, the sheet-like ground wiring PGND and the dielectric layer DLS configure a capacitor. Therefore, it is not necessary to form a decoupling capacitor separately from circuit elements on for example the semiconductor substrate of the semiconductor chip SC. Consequently, it is possible to make the main surface area of the semiconductor chip and the size of the semiconductor device smaller than in case of forming a decoupling capacitor separately on the semiconductor substrate SUB of the semiconductor chip.

Moreover, by forming the dielectric layer DLS of the foregoing material, it is possible to increase the capacitance of the decoupling capacitor which uses the sheet-like power supply wiring PPWR and the sheet-like ground wiring PGND as electrodes. Consequently, it is possible to operate the semiconductor device more stably.

Further, as shown in FIG. 8, in the wiring layer L9, the number of through vias VA89 (conductors filled in the second through holes) in each ground wiring GND coupled to the ground pad GPD is larger than the number of through vias VA89 (conductors filled in the first through holes) in each power supply wiring PWR disposed between the sheet-like power supply wiring PPWR and the power supply pad PPD.

By so doing, the electric resistance value of a through via VA89 formed under the ground wiring GND coupled with the ground pad GPD can be made smaller than the electric resistance value in a through via VA89 formed under the power supply wiring PWR coupled to the power supply pad PPD. As a result, electrical characteristics of the semiconductor device concerned can be more stabilized.

In this embodiment, the sheet-like power supply wiring PPWR and the power supply pads PPD are formed in the wiring layer L9. On the other hand, the sheet-like ground wiring PGND and the ground pads GPD are formed in different wiring layers L9 and L8. Therefore, an electrical coupling between the two is made by through vias VA89. Consequently, the electric resistance value between the sheet-like ground wiring PGND and the ground pads GPD is more likely to be higher than the electric resistance value between the sheet-like power supply wiring PPWR and the power supply pads PPD.

Therefore, as noted above, if the number of through vias VA89 which couple the sheet-like ground wiring PGND and the ground pads GPD electrically with each other is increased, a total sectional area of the through vias VA89 becomes substantially larger, with the result that it is possible to diminish the electric resistance value in the region concerned. More specifically, for example as shown in FIG. 8, by making the area of the power wiring PWR coupled to each power supply pad PPD larger than that of the ground wiring GND coupled to each ground pad GPD, it is possible to make the number of through vias VA89 coupled to the ground wiring GND larger than the number of through vias VA89 in the power supply wiring PWR.

Further, in this embodiment, on the main surface of the sheet-like ground wiring PGND, patterns PTN (through holes) are formed respectively in the regions intersecting the through vias VA89 (conductors filled in the third through holes) extending from the sheet-like power supply wiring PPWR. Thus, through vias VA89 are formed so as to be coupled to the sheet-like power supply wiring PPWR and the sheet-like ground wiring PGND and are positioned so as to pass through the patterns PTN (through holes) respectively, whereby it is possible to enhance the selection freedom for the regions where through vias VA89 can be formed.

For example, in case of each power supply wiring PWR and each ground wiring GND having a narrow elongated shape (linear shape) as in FIG. 11, the range where each through via VA89 can be formed is relatively narrow because it is in the interior of the power supply wiring PWR and the ground wiring GND. On the other hand, in this embodiment, patterns PTN and through vias VA89 can be formed in any region on the sheet-like power supply wiring PPWR and the sheet-like ground wiring PGND both spreading in a stratified form over a wide range.

In this embodiment, moreover, a plurality of slits (apertures) SLT are formed also in the sheet-like power supply wiring PPWR. Therefore, for example in case of flattening the wiring layer L9 including the sheet-like power supply wiring PPWR, it is possible to suppress the occurrence of variations in flatness between the sheet-like power supply wiring PPWR and the other regions.

The sheet-like power supply wiring PPWR and the sheet-like ground wiring PGND are large in surface area when seen in plan. Therefore, if the percent occupancy in the region where they are formed, (the ratio of the actually metal wirings (thin metallic films)-formed region relative to the entire region), is high, variations in the thickness of each wiring (thin metallic film) formed are likely to occur. Once such variations occur, then, at the time of polishing the surfaces of the thin metal films in a subsequent step, there is the possibility of occurrence of such an inconvenience as the thickness of the thin metallic films becoming partially smaller than in the other portion. The purpose of the polishing is to diminish variations in electric resistance value of the thin metallic films and facilitate the formation of an upper wiring layer in case of forming such a layer.

In this embodiment, however, slits SLT are formed in the sheet-like power supply wiring PPWR and the percent occupancy of the thin metallic films is set to for example a range of 70% to 80%. By so doing, the top surfaces of the thin metallic films formed can be made more flat. Consequently, local variations in electric resistance and a local increase of voltage drop, caused by variations in thickness of the thin metallic films formed, can be suppressed.

### Second Embodiment

In comparison with the first embodiment this second embodiment is different in the layout of a sheet-lie power supply wiring PPWR and a sheet-like ground wiring PGND. This second embodiment will be described below.

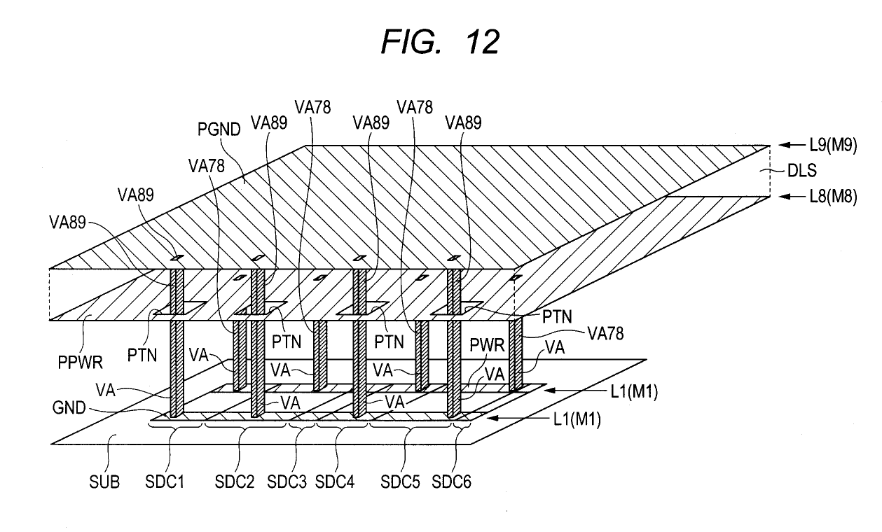

Referring to FIG. 12, in this second embodiment, a sheet-like ground wiring PGND is disposed in a wiring layer L9 as a top wiring layer and a sheet-like power supply wiring PPWR is disposed in a wiring layer L8. Only in this point the second embodiment is different from the first embodiment.

Thus, the sheet-like power supply wiring PPWR and the sheet-like ground wiring PGND may be formed in wiring layers vertically reverse to those in the semiconductor device of the first embodiment. Also in this case there are obtained the same effects as in the first embodiment. In this second embodiment, for example, the power supply wiring region PP in the wiring layer L9 shown in FIGS. 6 and 8 becomes a ground wiring region GG and the sheet-like power supply wiring PPWR in FIGS. 6 and 8 becomes a sheet-like ground wiring PGND. Likewise, the ground wiring region GG in the wiring layer L8 shown in FIGS. 7 and 9 becomes a power supply wiring region PP and the sheet-like ground wiring PGND in FIGS. 7 and 9 becomes a sheet-like power supply wiring PPWR.

This second embodiment is different in only the above points from the first embodiment. That is, the configurations, conditions, procedures and effects not referred to above in this second embodiment are all the same as in the first embodiment.

### Third Embodiment

This third embodiment is different in the configuration of wiring layers from the first embodiment. This third embodiment will be described below.

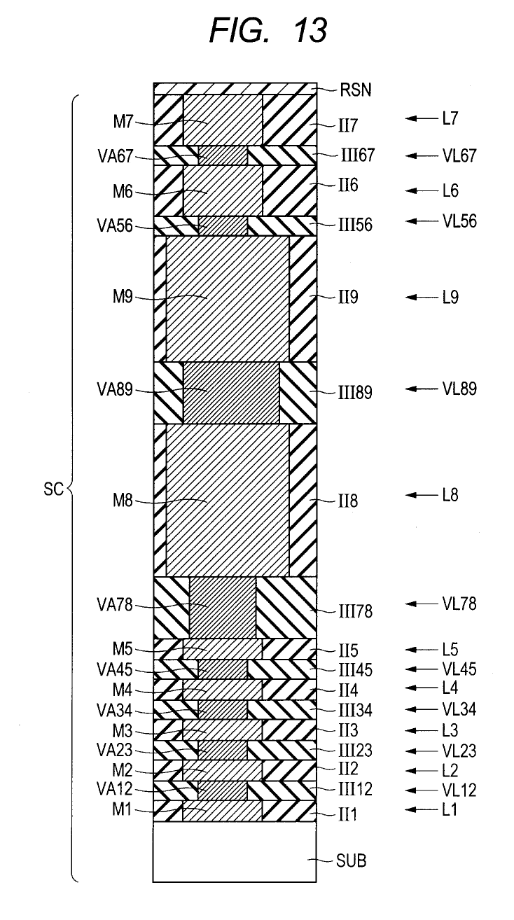

Referring to FIG. 13, in this third embodiment, wiring layers L7 and L6 overlie wiring layers L9 and L8. In this point this third embodiment is different from the first embodiment.

Thus, the sheet-like power supply wiring PPWR and the sheet-like ground wiring PGND need not always be disposed in the top layer of the multi-layer interconnection structure, but both may be disposed at arbitrary positions in the multi-layer interconnection structure.

Even in a configuration wherein the sheet-like power supply wiring PPWR and the sheet-like ground wiring PGND are disposed in such lower layers as wiring layers L7 and L6 wherein are formed ordinary wiring lines configuring the integrated circuit of the semiconductor chip SC, there are obtained the same effects as in the first embodiment. For example as in the second embodiment, a decoupling capacitor comprising the sheet-like ground wiring PGND in an upper layer and the sheet-like power supply wiring PPWR in a lower layer may be disposed in the lower wiring layers L7 and L6. Further, the sheet-like power supply wiring PPWR and the sheet-like ground wiring PGND may be disposed in layers of arbitrary heights, for example, such lower layers as wiring layers L4 and L3.

In only the above points this third embodiment is different from the first embodiment. That is, the configurations, conditions, procedures and effects not referred to above in this third embodiment are all the same as in the first embodiment.

### Fourth Embodiment

This fourth embodiment is different in the configuration of wiring layers from the first embodiment. This fourth embodiment will be described below.

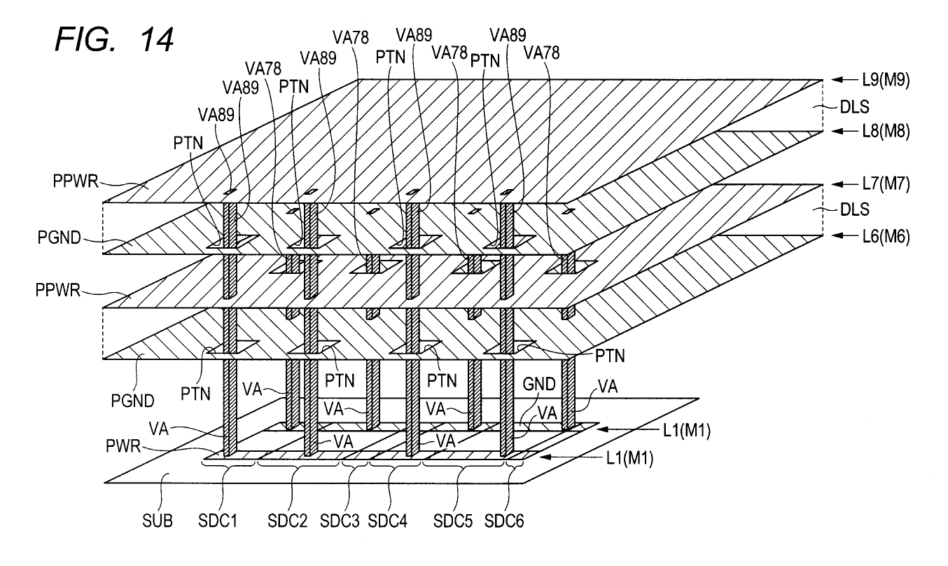

Referring to FIG. 14, in this fourth embodiment, a sheet-like power supply wiring PPWR and a sheet-like ground wiring PGND are disposed in wiring layers L7 and L6 respectively like wiring layers L9 and L8.

It is preferable for the wiring layers L7 and L6 to have the same configurations as the wiring layers L9 and L8 respectively except that patterns PTN for passing therethrough through vias VA which extend from through vias VA89 are formed in the wiring layers L7 and L6. For example, in the wiring layer L7 is disposed another sheet-like power supply wiring PPWR and in the wiring layer L6 is disposed another sheet-like ground wiring PGND. However, as in the second embodiment, a sheet-like ground wiring PGND may be disposed in the wiring layer L7 and a sheet-like power supply wiring PPWR may be disposed in the wiring layer L6. Also in the wiring layers L9 and L8 the vertical relation between the sheet-like power supply wiring PPWR and the sheet-like ground wiring PGND is arbitrary.

A dielectric layer DLS is disposed in the region where the power supply wiring region PP and the ground wiring region GG in the wiring layers L9 and L8 overlap each other in plan.

Likewise, a dielectric layer DLS is disposed in the region where the power supply wiring region PP and the ground wiring region GG in the wiring layers L7 and L6 overlap each other in plan. Thus, the semiconductor device of this fourth embodiment has a two-stacked configuration of decoupling capacitors as parallel plate capacitors.

In only the above points this fourth embodiment is different from the first embodiment. Also in the semiconductor device having the two-stacked configuration of decoupling capacitors as in this embodiment there are obtained the same effects as in the semiconductor device of the first embodiment.

In only the above points this fourth embodiment is different from the first embodiment. That is, the configurations, conditions, procedures and effects not referred to above in this fourth embodiment are all the same as in the first embodiment.

### Fifth Embodiment

In comparison with the first embodiment this fifth embodiment is different in the position where through vias VA and patterns PTN are formed in plan. This fifth embodiment will be described below.

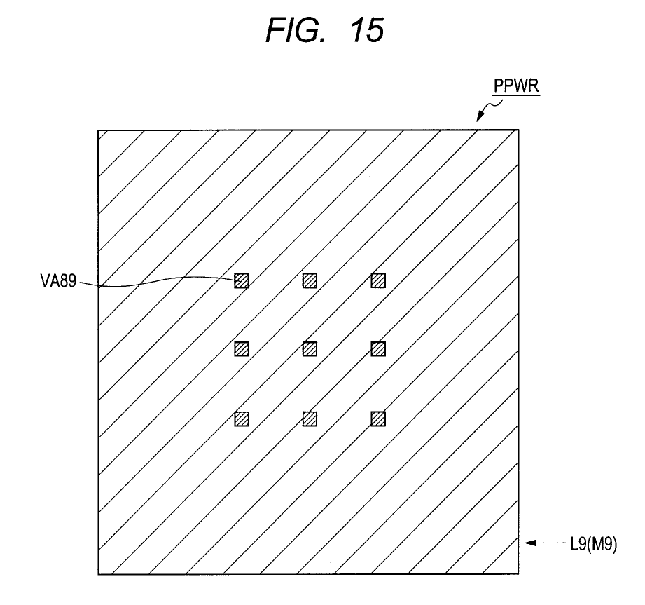

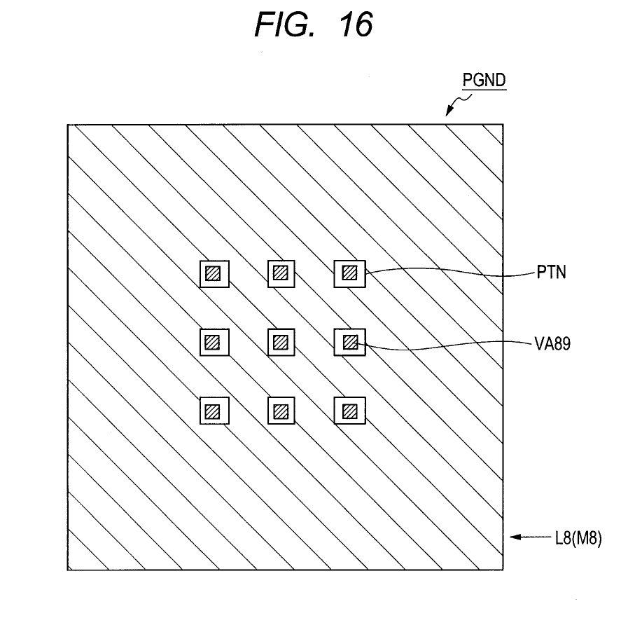

Referring to FIG. 15, in this fifth embodiment, for example coupling portions of through vias VA89 for coupling to a sheet-like power supply wiring PPWR in the wiring layer L9 are disposed concentratively at a central part of the sheet-like power supply wiring PPWR. That is, the density of coupling portions at positions coupled to through vias VA89 on a surface of the sheet-like power supply wiring PPWR is not uniform on the surface, but is different locally. FIG. 16 shows the layout of patterns PTN as through holes through which the through vias VA89 pass. Through vias VA89 in FIG. 16 are disposed at positions where they overlap the through vias VA89 in FIG. 15 when seen in plan.

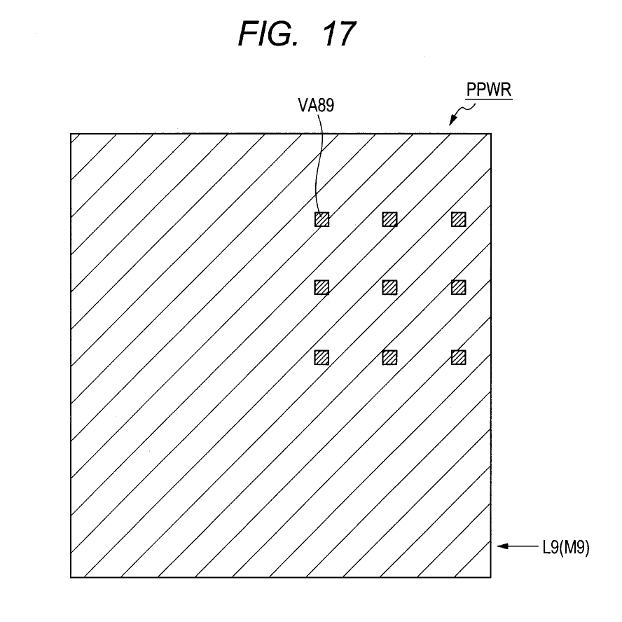

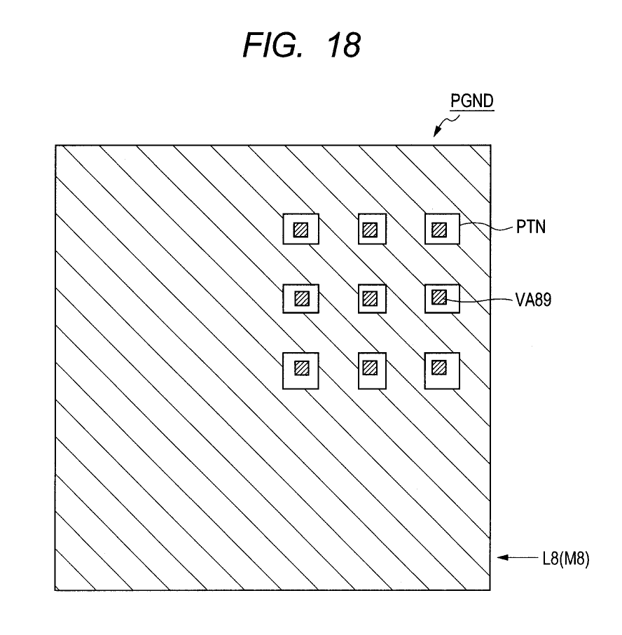

In FIGS. 17 and 18 showing examples different from FIG. 15, through vias VA89 (and patterns PTN) are disposed concentratively at a portion close to the outer periphery (for example, a portion close to the right upper corner) rather than the center in plan of the sheet-like power supply wiring PPWR and the sheet-like ground wiring PGND.

As in FIG. 16 referred to above, the through vias VA89 in FIG. 18 are disposed at positions where they overlap the through vias VA89 in FIG. 17. In the above points this fifth embodiment is different from the first embodiment.

Next, a description will be given about the function and effect of this fifth embodiment. In this fifth embodiment, as described above (explanation of FIG. 8), it is possible to widen an allowable range of the position where through vias VA for coupling between the sheet-like power supply wiring PPWR and the sheet-like ground wiring PGND are to be formed. This is because the surface area in plan of the sheet-like power supply wiring PPWR is large in comparison with related-art power supply wiring PWR and ground wiring GND.

As in this fifth embodiment, in the sheet-like power supply wiring PPWR and sheet-like ground wiring PGND spreading in a stratified form, particularly at an area of a large current consumption of the semiconductor chip SC or at a region overlapping a large voltage drop position of the supply voltage (a large electric resistance region in the current path from the power supply pad PPD), through vias VA (through vias VA89) are formed concentratively. With this arrangement, by supplying the supply current directly from the sheet-like power supply wiring PPWR to the region of a large voltage drop, it is possible to minimize the electric resistance value in the conducting path of the supply current and eventually lessen the voltage drop.

For example, the region of a specially large voltage drop in the semiconductor chip SC is generally a central part when seen in plan. Therefore, particularly in the case where the voltage drop at the central part is large, it is preferable that through vias VA (through vias VA89) be formed at the position shown in FIGS. 15 and 16. Through vias may be formed concentratively in an arbitrary region of a large current consumption or of a large voltage drop. Related examples are shown in FIGS. 17 and 18.

There may be adopted an arbitrary combination of this fifth embodiment with the first to third embodiments described above. For example, there may be adopted a configuration wherein a two-stacked structure of decoupling capacitors is further provided as in the fourth embodiment and such through vias as in this fifth embodiment are formed in each of the two and wherein wiring lines in a related integrated circuit are formed in the top layer as in the third embodiment.

In only the above points this fifth embodiment is different from the first embodiment. The configurations, conditions, procedures and effects not referred to above in this fifth embodiment are all the same as in the first embodiment.

It should be understood that the above embodiments are illustrative, not limitative, in all points. The scope of the present invention is shown not by the above descriptions but by the scope of claims and it is contemplated that all changes in meaning and scope equivalent to the scope of claims are included in the scope of the present invention.

### INDUSTRIAL APPLICABILITY

The present invention is applicable particularly advantageously to semiconductor devices having a stacked multilayer structure.

What is claimed is:

1. A semiconductor device comprising:
a semiconductor substrate having a main surface;
a sheet-like power supply wiring spreading in a stratified form along the main surface of the semiconductor substrate;
a sheet-like ground wiring spreading in a stratified form along the main surface of the semiconductor substrate and spacedly a predetermined certain distance from the sheet-like power supply wiring in a direction intersecting the main surface of the semiconductor substrate;
a power supply wiring formed over the main surface of the semiconductor substrate and extending in one direction within the main surface of the semiconductor substrate; and
a ground wiring formed over the main surface of the semiconductor substrate spacedly a predetermined certain distance from the power supply wiring and extending in a direction along the one direction,
wherein the sheet-like power supply wiring is electrically coupled with the power supply wiring, and
wherein the sheet-like ground wiring is electrically coupled with the ground wiring.

2. A semiconductor device according to claim 1,
wherein the sheet-like power supply wiring and the sheet-like ground wiring overlap each other at least partially when seen in plan, and
wherein a dielectric layer is disposed between the sheet-like power supply wiring and the sheet-like ground wiring.

3. A semiconductor device according to claim 2,
wherein the dielectric layer contains at least one member selected from the group consisting of silicon nitride, aluminum oxide, tantalum oxide, lanthanum oxide, hafnium oxide, zirconium oxide, silicate, aluminate, hafnium silicate, hafnium aluminum oxy-nitride, and yttrium oxide.

4. A semiconductor device according to any of claims 1 to 3, further comprising:
a first pad electrode and a second pad electrode both formed in the same layer as one of the sheet-like power supply wiring and the sheet-like ground wiring;
a first wiring portion formed in the same layer as the first pad electrode, the first wiring portion coupling one of the sheet-like power supply wiring and the sheet-like ground wiring with the first pad electrode;
a second wiring portion coupled to the second pad electrode and formed in the same layer as the first pad electrode;
a third wiring portion formed in the same layer as and coupled to the other of the sheet-like power supply wiring and the sheet-like ground wiring and disposed at a position overlapping the second wiring portion when seen in plan;
an interlayer dielectric film formed with a first through hole and a plurality of second through holes, the first through hole extending up to a region contacting the first wiring portion from between the second wiring portion and the third wiring portion and allowing at least a part of a surface of the first wiring portion to be exposed; and
a conductor filled in the interior of each of the first and second through holes,
wherein the number of the second through holes is larger than the number of the first through hole.

5. A semiconductor device according to claim 1, further comprising a conductor extending from the sheet-like power supply wiring so as to intersect the sheet-like ground wiring, the conductor coupling the sheet-like power supply wiring and the power supply wiring electrically with each other,
wherein the conductor is disposed so as to pass through a through hole formed in the sheet-like ground wiring.

6. A semiconductor device according to claim 1, wherein the sheet-like power supply wiring has a plurality of apertures in the interior thereof when seen in plan.

7. A semiconductor device according to claim 1, wherein the density in plan of coupling portions coupled electrically with the power supply wiring in the sheet-like power supply wiring is different locally in the sheet-like power supply wiring.
